(19) United States
(12) Patent Application Publication
(10) Pub. No.: US 2025/0289980 A1
(43) Pub. Date: Sep. 18, 2025

(54) FILM-LIKE ADHESIVE AGENT, ADHESIVE FILM, DICING/DIE-BONDING INTEGRATED FILM, AND PRODUCTION METHOD FOR SEMICONDUCTOR DEVICE

(71) Applicant: Resonac Corporation, Minato-ku, Tokyo (JP)

(72) Inventors: Michiko KAYA, Minato-ku, Tokyo (JP); Shota AOYAGI, Minato-ku, Tokyo (JP)

(21) Appl. No.: 18/859,996

(22) PCT Filed: Aug. 9, 2023
(86) PCT No.: PCT/JP2023/029171

§ 371 Date: Oct. 25, 2024

(30) Foreign Application Priority Data
Sep. 14, 2022 (JP) 2022-146281

(51) Int. Cl. C09J 7/30; C09J 11/00; C09J 119/00; H01L 21/683; H01L 23/00

(52) U.S. Cl. CPC C09J 7/30; C09J 11/00; C09J 119/00; H01L 21/6836; H01L 24/29; H01L 24/83; H01L 24/97; C09J 2203/326; C09J 2433/00; H01L 2221/68327; H01L 2221/68377; H01L 2224/29191; H01L 2224/83862; H01L 2224/97; H01L 2924/365

(57) ABSTRACT

A film-like adhesive containing a thermosetting resin component and a filler, in which the film-like adhesive has a single layer structure including a first surface and a second surface, and has a region A in the vicinity of the first surface, the region in which a content of the filler decreases in a direction from the second surface toward the first surface, and a region B in which the content of the filler does not substantially change in a direction from the region A toward the second surface, in which when the film-like adhesive is cured, the film-like adhesive satisfies Formula (1) below:

$$a \times ( b / c ) > 50 \qquad ( 1 )$$

in which a thickness of a region A after thermal curing is a (nm), an elastic modulus of a region B is b (Pa), and an elastic modulus at a cleaved surface of mica is c (Pa).

### TECHNICAL FIELD

The present disclosure relates to a film-like adhesive, an adhesive film, a dicing/die-bonding integrated film, and a method for manufacturing a semiconductor device.

### BACKGROUND ART

In recent years, with the increase in functionality and speed of smartphones, tablet PCs, and the like, semiconductor packages used for them have been required to be further reduced in size, increased in capacity, increased in speed, reduced in thickness, and the like. In a wafer used in such a semiconductor package, further miniaturization of the wiring thereof is progressing, and a chip tends to be further thinned when the semiconductor package is assembled.

Under such a tendency, particularly in the fields of DRAM and NAND flash memories, a problem that an operation failure occurs due to an extremely small amount of heavy metal ions such as copper ions has started to become apparent. When the heavy metal ions come into contact with the silicon crystal, the heavy metal ions may diffuse into the crystal and reach the circuit surface, and this is known to cause an operation failure. From the viewpoint of preventing occurrence of an operation failure, in assembly of a semiconductor package, it is common to perform gettering processing for trapping heavy metal ions on a silicon wafer so that heavy metal ions attached to the silicon wafer do not diffuse to a circuit surface.

As the gettering processing, for example, a method of providing a gettering layer inside the wafer (intrinsic gettering, hereinafter referred to as “IG”) and a method of providing a gettering layer on the back surface of the wafer (extrinsic gettering, hereinafter referred to as “EG”) are mainly used. However, in the IG, the thickness of the gettering layer that can be formed inside is reduced due to the thinning of the chip, and the effect is not sufficient. In addition, in the EG, since minute cracks are formed on the back surface of the wafer, the deflective strength of the chip decreases. Therefore, there is a problem that it is difficult to perform excessive gettering processing particularly in an ultrathin wafer that is difficult to handle. Under such circumstances, it has been studied to impart a gettering function for capturing heavy metal ions in a resin film (an adhesive film used in a manufacturing process of a semiconductor device), more specifically, a film-like adhesive (die-bonding film) used for adhesion between chips and a substrate or between chips (see, for example, Patent Literature 1 and Patent Literature 2).

### CITATION LIST

### Patent Literature

Patent Literature 1: Japanese Unexamined Patent Publication No. 2011-213878

Patent Literature 2: Japanese Unexamined Patent Publication No. 2012-241157

### SUMMARY OF INVENTION

### Technical Problem

However, the film-like adhesive in the related art is not sufficient in suppressing defects associated with movement of copper ions in the adhesive, and there is still room for improvement. The present disclosure provides a film-like adhesive having a barrier function of preventing movement of heavy metal ions, for example, copper ions, and an adhesive film including the same. The present disclosure also provides a dicing/die-bonding integrated film including a film-like adhesive as a first adhesive layer, and a method for manufacturing a semiconductor device using the same.

### Solution to Problem

A film-like adhesive formed of a resin composition having thermosetting properties and containing a filler, the film-like adhesive having a single layer structure including a first surface and a second surface, in which the film-like adhesive has a region A in a vicinity of the first surface, the region in which a content of the filler decreases from the second surface side toward the first surface side; and a region B in which the content of the filler does not substantially change from the region A of the film-like adhesive toward the second surface side, in which when the film-like adhesive is cured by heating, the film-like adhesive satisfies Formula (1) below:

$$a \times ( b / c ) > 50 \qquad ( 1 )$$

in which a thickness of a region A of the film-like adhesive after thermal curing is a (nm), an elastic modulus of a region B is b (Pa), and an elastic modulus at a cleaved surface of mica is c (Pa).

The state where the film-like adhesive is cured by heating means a state where the reaction rate is 90% or more in a general method for evaluating the degree of curing by comparing the calorific values before and after reaction by differential scanning calorimetry (DSC, for example, Thermo Plus 2 manufactured by Rigaku Holdings Corporation). In order to cure the film-like adhesive, for example, heating may be performed at 170° C. for 3 hours.

The film-like adhesive having the region A has a barrier function of preventing movement of heavy metal ions. The reason for this is not necessarily clear, but the present inventors infer as follows. That is, the fact that the content of the filler in the region located in the vicinity of the first surface is relatively low means that, in other words, in the vicinity of the first surface, a region (resin-rich region) in which the content of the resin component is relatively high is locally formed in the thickness direction, and on the other hand, formed with a continuous spread in the plane direction. As a result, it can be said that the region A is denser than other regions (for example, region B), and it is presumed that the region A exhibits a barrier function of preventing the movement of heavy metal ions by having a certain thickness. Furthermore, since the film-like adhesive has the region B in addition to the region A, and the region B has an elastic modulus of a certain size (that is, it has a certain degree of hardness), it can be said that the region B is also dense to a certain extent, and it is inferred that the region B exhibits a barrier function of preventing movement of heavy metal ions.

An adhesive film according to the present disclosure is an adhesive film including the film-like adhesive according to the first aspect or a second aspect and a base film in contact with the second surface of the film-like adhesive. A dicing/die-bonding integrated film according to the present disclosure includes, in this order, a first adhesive layer including the film-like adhesive according to the first or second aspect, a second adhesive layer in contact with a second surface of the film-like adhesive, a first adhesive layer in contact with the second adhesive layer, and a base film in contact with the first adhesive layer.

A method for manufacturing a semiconductor device according to the present disclosure includes attaching a wafer onto the first surface of the film-like adhesive (first adhesive layer) in the dicing/die-bonding integrated film, singulating the wafer and the film-like adhesive into a plurality of adhesive piece-attached chips, picking up the adhesive piece-attached chip from the second adhesive layer, and bonding the chip onto a substrate or another chip via the adhesive piece.

### Advantageous Effects of Invention

According to the present disclosure, there are provided a film-like adhesive having a barrier function of preventing movement of heavy metal ions, for example, copper ions, and an adhesive film including the same. Furthermore, according to the present disclosure, there are provided a dicing/die-bonding integrated film including a film-like adhesive as a first adhesive layer, and a method for manufacturing a semiconductor device using the same.

### BRIEF DESCRIPTION OF DRAWINGS

FIG. 1 is a cross-sectional view schematically illustrating one embodiment of a film-like adhesive according to the present disclosure.

FIG. 2 is an example of a graph obtained when the film-like adhesive according to the present disclosure is subjected to indentation measurement.

(a) and (b) in FIG. 3 are examples of graphs obtained when indentation measurement is not correctly performed.

(a) and (b) in FIG. 4 are examples of graphs obtained when indentation measurement is not correctly performed.

(a) and (b) in FIG. 5 are examples of graphs obtained when indentation measurement is not correctly performed.

FIG. 6 is an example of a graph obtained when indentation measurement is not correctly performed.

FIG. 7 is a cross-sectional view schematically illustrating an example of an adhesive film including the film-like adhesive illustrated in FIG. 1.

FIG. 8 is a cross-sectional view schematically illustrating one embodiment of a dicing/die-bonding integrated film according to the present disclosure.

FIG. 9 is a cross-sectional view schematically illustrating an example of a semiconductor device.

FIG. 10 is a cross-sectional view schematically illustrating another example of the semiconductor device.

FIG. 11 is a cross-sectional view schematically illustrating another embodiment of the film-like adhesive according to the present disclosure.

### DESCRIPTION OF EMBODIMENTS

Hereinafter, embodiments of the present disclosure will be described with appropriate reference to the drawings. However, the present disclosure is not limited to the following embodiments. In the following embodiments, the components (including steps and the like) are not essential unless otherwise specified. The sizes of the components in the drawings are conceptual, and the relative relationship between the sizes of the components is not limited to that illustrated in the drawings.

The same applies to numerical values and ranges thereof in the present specification, and the present invention is not limited thereto. In the present specification, a numerical range specified using “to” indicates a range including the numerical values written before and after “to” as a minimum value and a maximum value, respectively. In the numerical ranges described in stages in the present specification, the upper limit value or the lower limit value described in one numerical range may be replaced with the upper limit value or the lower limit value of the numerical range described in another stage. In addition, in the numerical range described in the present specification, the upper limit value or the lower limit value of the numerical range may be replaced with a value shown in examples. In the present specification, (meth)acrylate means an acrylate or a methacrylate corresponding thereto. The same applies to other similar expressions such as a (meth)acryloyl group and a (meth)acrylic copolymer.

### Film-Like Adhesive

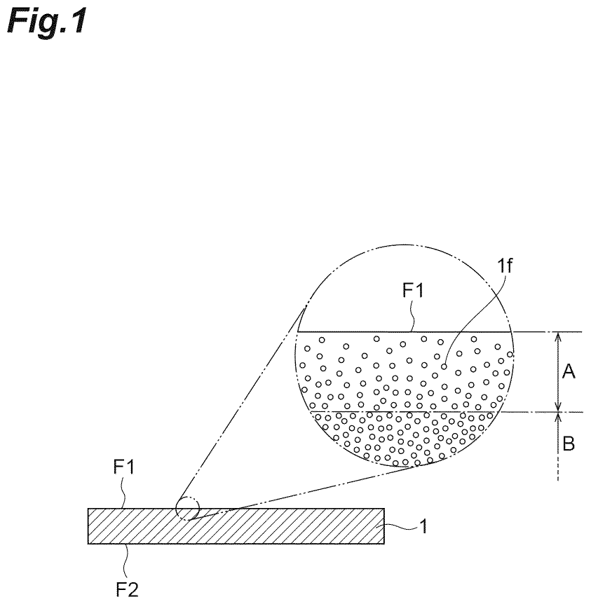

FIG. 1 is a cross-sectional view schematically illustrating a film-like adhesive according to the present embodiment. A film-like adhesive 1 illustrated in this drawing has a single-layer structure formed of a resin composition having a thermosetting property and containing a filler. The thickness of the film-like adhesive 1 may be 50 μm or less, and may be, for example, 40 μm or less, 30 μm or less, 20 μm or less, or 10 μm or less. When the thickness of the film-like adhesive 1 is 50 μm or less, the distance between the semiconductor element and the support member on which the semiconductor element is mounted becomes short, so that defects due to heavy metal ions tend to easily occur, and thus the effect of the present invention is easily obtained. The lower limit of the thickness of the film-like adhesive 1 is not particularly limited, but is, for example, 2 μm or more. When the thickness of the film-like adhesive 1 is 2 μm or more, a film having a better appearance tends to be easily obtained.

The film-like adhesive 1 has, in the vicinity of a first surface F1, a region A (a region indicated by an arrow in the enlarged view illustrated in FIG. 1) in which the content of the filler decreases from a second surface F2 side toward the first surface F1 side. The region A includes a plurality of particles of filler 1f and a resin component. In the region

A, the content of the filler 1f may continuously decrease or may gradually decrease. The region A plays a role of preventing movement of heavy metal ions. That is, the fact that the content of the filler 1f in the region A located in the vicinity of the first surface F1 is relatively low means that, in other words, in the vicinity of the first surface F1, a region (resin-rich region) in which the content of the resin component is relatively high is locally formed in the thickness direction, and on the other hand, is formed with a continuous spread in the plane direction. Since such the region A is denser than other regions, it is presumed that the region A has a barrier function of preventing movement of heavy metal ions.

The region A according to the present embodiment varies depending on the thickness of the film-like adhesive 1, but is positioned at a position where a depth from the first surface F1 is shallower than the position of 2 μm. In other words, the “vicinity of the first surface F1” in the present embodiment means a region where the depth from the first surface F1 is shallower than the position of 2 μm. It is sufficient that the region A exists in the vicinity of the first surface F1, and for example, a region having a high content of the filler 1f may locally exist on the first surface F1.

The film-like adhesive 1 has the region B in which the content of the filler 1f does not substantially change in the direction from the region A toward the second surface F2 side. The region B includes a plurality of fillers 1f and a resin component.

The thickness of the region A and the elastic modulus of the region B can be confirmed by performing indentation measurement from the first surface F1 using an atomic force microscope (AFM). A measurement method of the thickness of the region A and the elastic modulus of the region B by the indentation measurement is as follows.

First, the film-like adhesive is cured, the cured film-like adhesive is fixed on a sample stage of an atomic force microscope (for example, SPM400 manufactured by Hitachi High-Tech Corporation), and a cantilever (for example, SI-DF-40 manufactured by Hitachi High-Tech Corporation) is placed on a cantilever holder to obtain a force curve. The force curve is a curve indicating the load applied to the cantilever with respect to the displacement of the piezoelectric element. When the force curve is obtained, the depth of pushing into the sample is equal to or greater than the thickness of the region A. The indentation depth is calculated from a force curve of a region where the cantilever is pressed into the sample, and can be limited by measurement conditions and device conditions. For example, the indentation depth is preferably 500 nm or more, and more preferably 1000 nm or more. The indentation depth needs to be at least a depth at which the region A can be ascertained or more. The force curve in the region where the cantilever is pushed into the sample is an applied load-indentation depth curve obtained by continuously measuring the load applied to the indenter and the indentation depth when the indenter (cantilever) is pushed into the sample. The indentation depth is about 1000 nm. The force curve of the obtained pressed region is converted into a curve indicating the relationship between the elastic modulus and the distance from the first surface (the indentation depth of the cantilever) using the Hertz contact theory. At this time, the cantilever spring constant is corrected, the state of the cantilever is monitored, and the cantilever is replaced when obvious wear, deterioration, or the like is observed.

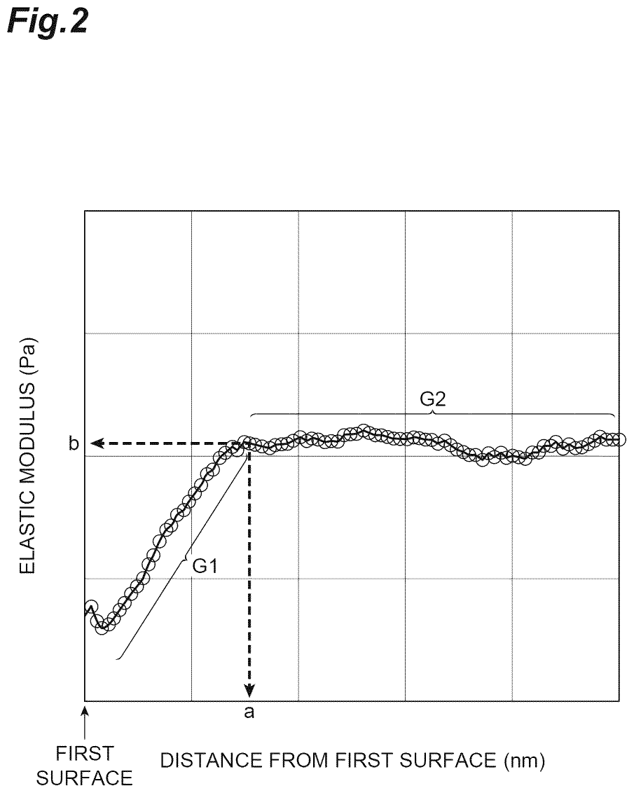

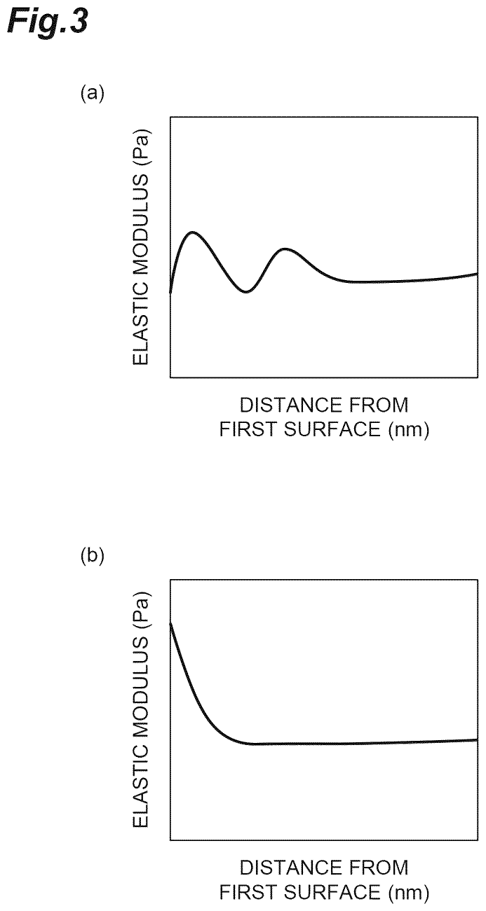

An example of a curve converted from the force curve in the region where the cantilever is pushed into the sample by the Hertz contact theory is shown in FIG. 2. Since the content of the filler 1f increases from the first surface F1 side toward the second surface F2 side in the region A, the elastic modulus tends to gradually increase in the curve in FIG. 2 (G1 portion illustrated in FIG. 2). On the other hand, since the content of the filler 1f does not substantially change in a region B (a region from the region A toward the second surface F2) that is a region deeper in the thickness direction than the region A, the elastic modulus shows a substantially constant value in the curve in FIG. 2 (G2 portion illustrated in FIG. 2).

Since the elastic modulus of the film-like adhesive is different between the region A and the region B, the behavior of the curve changes at the boundary between the region A and the region B. Therefore, the intersection of the G1 portion and the G2 portion of the curve can be regarded as the thickness a (nm) of the region A. A thickness a of the region A is an average value of 10 times of indentation measurement of the film-like adhesive.

The thickness a of the region A is, for example, 0.05 to 2 μm, and may be 0.1 to 1.5 μm or 0.3 to 1 μm. When the thickness a of the region A is 0.05 μm or more, the region A tends to play a role of hindering the movement of heavy metal ions, and further, when the thickness a of the region A is 0.1 μm or more, the region A tends to sufficiently play a role of hindering the movement of heavy metal ions. On the other hand, when the thickness a of the region A is 2 μm or less, the handleability of the film-like adhesive 1 tends to be easily maintained. The ratio of the thickness a of the region A to the total thickness of the film-like adhesive 1 is, for example, 0.3 to 25%, and may be 1 to 20% or 3 to 15%. When the ratio is 0.3% or more, the region A tends to play a role of hindering the movement of heavy metal ions, and when the ratio is 1% or more, the region A tends to sufficiently play a role of hindering the movement of heavy metal ions. On the other hand, when the ratio is 25% or less, an effect that the mechanical strength of the film-like adhesive 1 can be maintained is exhibited.

Since the composition of the region B is uniform, the content of the filler 1f does not substantially change. Therefore, the G2 portion of the curve is flat, and the elastic modulus at the intersection of the G1 portion and the G2 portion of the curve can be regarded as the elastic modulus b (Pa) of the region B. An elastic modulus b of the region B is an average value when the film-like adhesive is subjected to indentation measurement 10 times.

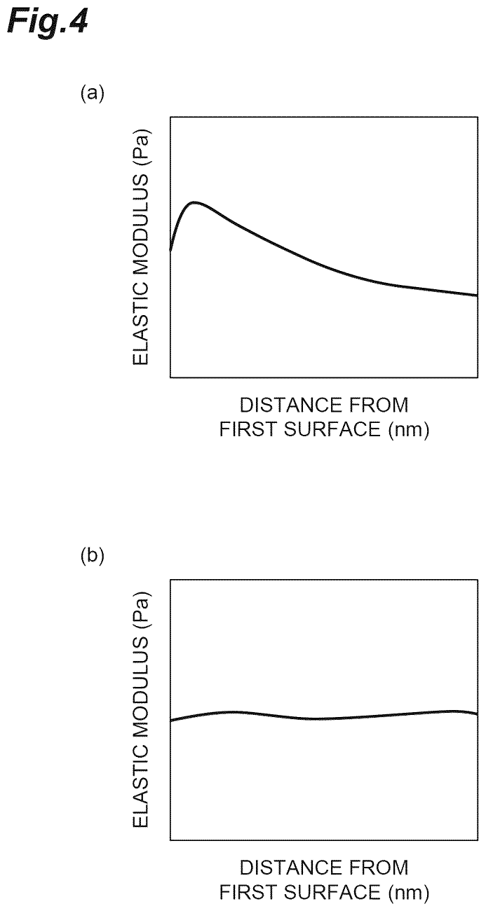

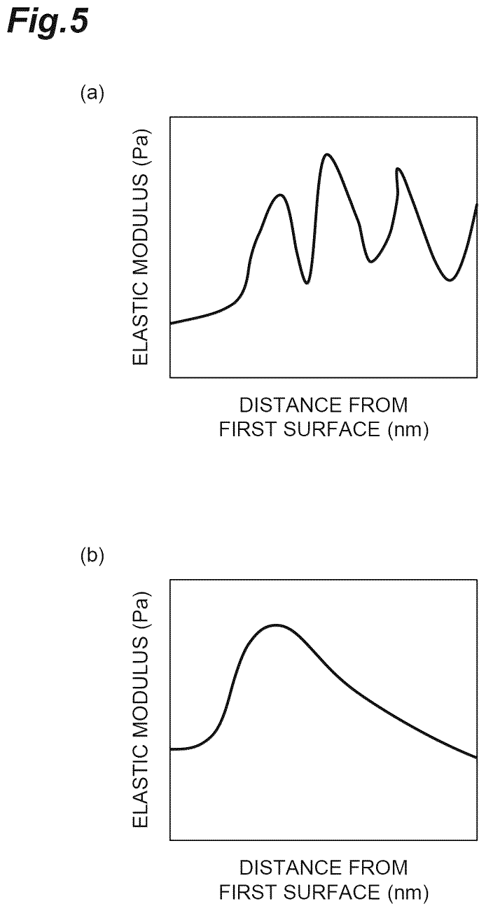

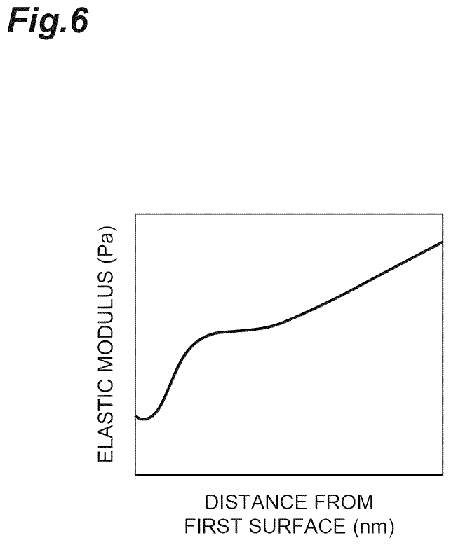

In a case where the film-like adhesive 1 does not have the region A, a result as illustrated in FIG. 2 cannot be obtained. In addition, in the indentation measurement using an atomic force microscope, since the local elastic modulus of the resin component on the first surface F1 is measured, even if the film-like adhesive 1 has the region A and the region B, the result as illustrated in FIG. 2 may not be obtained. For example, when the cantilever comes into contact with the filler 1f in the indentation measurement, the elastic modulus of the resin component cannot be correctly measured, and a graph illustrating the relationship between the elastic modulus and the distance from the first surface as illustrated in FIG. 2 cannot be obtained. FIGS. 3 to 6 illustrate an example of a graph obtained in a case where the indentation measurement is not correctly performed. It is to be noted that the film-like adhesive according to the present embodiment can obtain the results as illustrated in FIG. 2 5 or more times when the indentation measurement is performed 10 times.

In a case where the following (1) and (2) are satisfied, it can be determined that the indentation measurement has been correctly performed in the present invention.
(1) As the distance from the first surface increases from the start of measurement of the elastic modulus (left end of the graph), the elastic modulus increases substantially monotonically (the graph illustrating the relationship between the elastic modulus and the distance from the first surface has the G1 portion illustrated in FIG. 2).
(2) After the elastic modulus increases substantially monotonically, the elastic modulus is substantially constant (the graph illustrating the relationship between the elastic modulus and the distance from the first surface has the G2 portion illustrated in FIG. 2).

In the indentation measurement, the measurement result of the elastic modulus can change depending on the state of the cantilever. Therefore, when the elastic modulus of the region B is evaluated using the managed cantilever, the elastic modulus of the region B is normalized using the elastic modulus of mica using mica as a standard sample. The film-like adhesive according to the present embodiment satisfies Formula (1) below when the elastic modulus at the cleaved surface of mica is c (Pa). Note that an elastic modulus c of mica means a value measured by the same method as the indentation measurement for the film-like adhesive with respect to the cleaved surface immediately after (for example, within 60 minutes) cleaving mica. As the thickness of cleaved mica used for the measurement (the thickness in the direction in which the cantilever is pushed), one having a certain thickness (for example, 5 μm or more) is used. Specifically, the elastic modulus c of mica can be measured by a method described in examples described later.

$$a \times ( b / c ) > 50 \qquad ( 1 )$$

When an expression of a×(b/c)=X is established, X may be 70 nm or more, 100 nm or more, 110 nm or more, 120 nm or more, 130 nm or more, 140 nm or more, 150 nm or more, 160 nm or more, or 170 nm or more. When X is 130 nm or more, it tends to sufficiently play a role of hindering movement of heavy metal ions.

When an expression of b/c=Y is established, Y may be 0.01 or more, 0.05 or more, 0.1 or more, 0.15 or more, or 0.2 or more. When Y is 0.1 or more, it tends to sufficiently play a role of hindering movement of heavy metal ions.

The film-like adhesive 1 is formed of an adhesive composition containing a thermosetting resin component (A) and a filler (B). The film-like adhesive 1 may pass through a semi-cured (B-stage) state and may be in a cured (C-stage) state after a curing treatment. In one embodiment, the thermosetting resin component (A) may include a thermosetting resin (A1), a curing agent (A2), and an elastomer (A3).

### Component (A1): Thermosetting Resin

The component (A1) may be an epoxy resin from the viewpoint of adhesiveness. The epoxy resin can be used without particular limitation as long as it has an epoxy group in the molecule. Examples of the epoxy resin include bisphenol A type epoxy resins, bisphenol F type epoxy resins, bisphenol S type epoxy resins, phenol novolac type epoxy resins, cresol novolac type epoxy resins, bisphenol A novolac type epoxy resins, bisphenol F novolac type epoxy resins, stilbene type epoxy resins, triazine skeleton-containing epoxy resins, fluorene skeleton-containing epoxy resins, triphenol methane type epoxy resins, biphenyl type epoxy resins, xylylene type epoxy resins, biphenyl aralkyl type epoxy resins, naphthalene type epoxy resins, polyfunctional phenols, diglycidyl ether compounds of polycyclic aromatics such as anthracene, and the like. These may be used singly or in combination of two or more kinds thereof. Among them, the component (A1) may be a cresol novolac type epoxy resin, a phenol novolac type epoxy resin, a bisphenol F type epoxy resin, or a bisphenol A type epoxy resin from the viewpoint of tackiness, flexibility, and the like of the film.

An epoxy equivalent of the epoxy resin is not particularly limited, but may be 90 to 300 g/eq or 110 to 290 g/eq. When the epoxy equivalent of the epoxy resin is in such a range, fluidity tends to be secured while the bulk strength of the film-like adhesive is maintained.

### Component (A2): Curing Agent

The component (A2) may be a phenolic resin that can serve as a curing agent for the epoxy resin. The phenol resin can be used without particular limitation as long as it has a phenolic hydroxyl group in the molecule. Examples of the phenol resin include novolac-type phenolic resins obtained by condensing or co-condensing phenols such as phenol, cresol, resorcin, catechol, bisphenol A, bisphenol F, phenylphenol, aminophenol, or the like and/or naphthols such as a-naphthol, ß-naphthol, dihydroxynaphthalene, or the like with compounds having an aldehyde group such as formaldehyde under an acidic catalyst; phenol aralkyl resins synthesized from phenols such as allylated bisphenol A, allylated bisphenol F, allylated naphthalenediol, phenol novolac, phenol, or the like and/or naphthols with dimethoxy-para-xylene or bis(methoxymethyl)biphenyl, and naphthol aralkyl resins. These may be used singly or in combination of two or more kinds thereof. Among them, the phenolic resin may be a novolac-type phenolic resin or a naphthol aralkyl resin.

The hydroxyl group equivalent of the phenol resin may be 70 g/eq or more or 70 to 300 g/eq. When the hydroxyl group equivalent of the phenol resin is 70 g/eq or more, the storage elastic modulus of the film tends to be further improved, and when the hydroxyl group equivalent of the phenol resin is 300 g/eq or less, defects due to foaming, generation of outgas, and the like can be prevented.

The ratio of the epoxy equivalent of the epoxy resin to the hydroxyl equivalent of the phenol resin (epoxy equivalent of epoxy resin/hydroxyl group equivalent of phenol resin) may be 0.30/0.70 to 0.70/0.30, 0.35/0.65 to 0.65/0.35, 0.40/0.60 to 0.60/0.40, or 0.45/0.55 to 0.55/0.45 from the viewpoint of curability. When the equivalent ratio is 0.30/0.70 or more, more sufficient curability tends to be obtained.

When the equivalent ratio is 0.70/0.30 or less, the viscosity can be prevented from becoming too high, and more sufficient fluidity can be obtained.

The total content of the component (A1) and the component (A2) may be 5 to 50 parts by mass, 10 to 40 parts by mass, or 15 to 30 parts by mass with respect to 100 parts by mass of the total mass of the component (A). When the total content of the component (A1) and the component (A2) is 5 parts by mass or more, the elastic modulus tends to be improved by crosslinking. When the total content of the component (A1) and the component (A2) is 50 parts by mass or less, film handleability tends to be maintained.

### Component (A3): Elastomer

The component (A3) may be an acrylic rubber containing a constituent unit derived from a (meth)acrylic acid ester as a main component. The content of the constituent unit derived from the (meth)acrylic acid ester in the component (A3) may be, for example, 70 mass % or more, 80 mass % or more, or 90 mass % or more based on the total amount of the constituent units. The acrylic rubber may contain a constituent unit derived from a (meth) acrylic acid ester having a crosslinkable functional group such as an epoxy group, an alcoholic or phenolic hydroxyl group, or a carboxyl group. In addition, the component (A3) may contain a constituent unit derived from acrylonitrile, but the component (A3) may not contain a constituent unit derived from acrylonitrile because permeation of heavy metal ions in the adhesive can be further suppressed, and the component (A3) is more excellent in embeddability.

The glass transition temperature (Tg) of the component (A3) may be −50 to 50° C. or −30 to 30° C. When the Tg of the component (A3) is −50° C. or higher, it tends to be possible to prevent the flexibility of the adhesive from becoming too high. As a result, the film-like adhesive is easily cut at the time of wafer dicing, and generation of burrs can be prevented. When the Tg of the component (A3) is 50° C. or lower, a decrease in flexibility of the adhesive tends to be suppressed. As a result, when the film-like adhesive is attached to the wafer, voids tend to be easily embedded sufficiently. In addition, it is possible to prevent chipping at the time of dicing due to a decrease in adhesion of the wafer. Here, the glass transition temperature (Tg) means a value measured using differential scanning calorimetry (DSC) (for example, Thermo Plus 2 manufactured by Rigaku Holdings Corporation).

The weight average molecular weight (Mw) of the component (A3) may be 100,000 to 3 million or 200,000 to 2 million. When the Mw of the component (A3) is in such a range, the film formability, the strength in the form of a film, the flexibility, the tackiness, and the like can be appropriately controlled, the reflowability is excellent, and the embeddability can be improved. Here, Mw means a value measured by gel permeation chromatography (GPC) and converted using a calibration curve by standard polystyrene.

Examples of commercially available products of the component (A3) include an SG-P3 modified product and SG-80H (both manufactured by Nagase ChemteX Corporation).

The content of the component (A3) may be 50 to 95 parts by mass, 60 to 90 parts by mass, or 70 to 85 parts by mass with respect to 100 parts by mass of the total mass of the component (A). When the content of the component (A3) is in such a range, movement (permeation) of heavy metal ions in the adhesive tends to be more sufficiently suppressed. When the component (A3) is an acrylic rubber, the content of the acrylic rubber is, for example, 50 to 85 mass %, and may be 55 to 80 mass % or 60 to 80 mass % based on the total mass of the adhesive composition. When the content is 50 mass % or more, an effect that the region R1 is easily formed is exerted, and on the other hand, when the content is 85 mass % or less, an effect that workability in production of the film-like adhesive 1 is easily maintained is exerted.

In another embodiment, the thermosetting resin component (A) may contain an elastomer having a crosslinkable functional group such as an epoxy group, an alcoholic or phenolic hydroxyl group, or a carboxyl group, and a curing agent capable of reacting with the crosslinkable functional group. Examples of the combination of the elastomer having a crosslinkable functional group and the curing agent capable of reacting with the crosslinkable functional group include a combination of an acrylic rubber having an epoxy group and a phenol resin.

### Component (B): Filler

The component (B) may be either an inorganic filler or an organic filler. Examples of the inorganic filler include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, and silica. These may be used singly or in combination of two or more kinds thereof. Among them, the component (B) may be silica from the viewpoint of adjusting the melt viscosity. Examples of the organic filler include carbon, rubber-based fillers, silicone-based fine particles, polyamide fine particles, and polyimide fine particles. The shape of the component (B) is not particularly limited, but may be spherical.

The average particle diameter of the component (B) may be 0.01 to 1 μm, 0.01 to 0.8 μm, or 0.03 to 0.5 μm from the viewpoint of fluidity. Here, the average particle diameter means a value obtained by conversion from the BET specific surface area.

The content of the component (B) may be 0.1 to 50 parts by mass, 0.1 to 30 parts by mass, or 0.1 to 20 parts by mass with respect to 100parts by mass of the total mass of the component (A). Based on the total mass of the adhesive composition, the content of the component (B) is, for example, 3 to 55 mass %, and may be 5 to 50 mass % or 7 to 40 mass %. When the content is 3% by mass or more, an effect of retaining the mechanical strength of the film-like adhesive 1 is exerted, and on the other hand, when the content is 55% by mass or less, an effect of retaining a good appearance of the film-like adhesive 1 is exerted.

The film-like adhesive (adhesive composition) may further contain a coupling agent (C), a curing accelerator (D), and the like.

### Component (C): Coupling Agent

The component (C) may be a silane coupling agent. Examples of the silane coupling agent include γ-ureidopropyltriethoxysilane, γ-mercaptopropyltrimethoxysilane, 3-phenylaminopropyltrimethoxysilane, and 3-(2-aminoethyl) aminopropyltrimethoxysilane. These may be used singly or in combination of two or more kinds thereof.

### Component (D): Curing Accelerator

The component (D) is not particularly limited, and those generally used can be used. Examples of the component (D) include imidazoles and derivatives thereof, organophosphorus compounds, secondary amines, tertiary amines, and quaternary ammonium salts. These may be used singly or in combination of two or more kinds thereof. Among them, the component (D) may be imidazoles and derivatives thereof from the viewpoint of reactivity. Examples of the imidazoles include 2-methylimidazole, 1-benzyl-2-methylimidazole, 1-cyanoethyl-2-phenylimidazole, and 1-cyanoethyl-2-methylimidazole. These may be used singly or in combination of two or more kinds thereof.

The film-like adhesive 1 may further contain other components. Examples of other components include a leveling agent, a pigment, an ion scavenger, and an antioxidant. The content of the component (C), the component (D), and other components may be 0 to 30 parts by mass with respect to 100 parts by mass of the total mass of the component (A).

### Method for Manufacturing Film-Like Adhesive

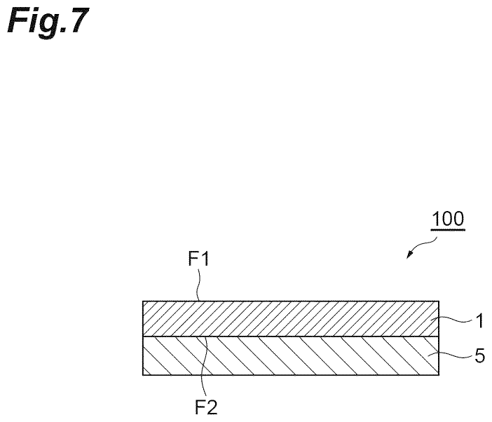

The film-like adhesive 1 can be formed by applying an adhesive composition to a support film. In a case where the varnish (adhesive varnish) of the adhesive composition is used, the film-like adhesive I can be obtained through the processes of mixing the component (A) and the component (B), and other components added as necessary in a solvent, mixing or kneading the mixed liquid to prepare an adhesive varnish, applying the adhesive varnish to a support film 5, and removing the solvent by drying. An adhesive sheet 100 illustrated in FIG. 7 is composed of a support film 5 and a film-like adhesive 1 provided on the surface of the support film 5.

When the film-like adhesive 1 is formed from the coating film of the adhesive varnish, the region R1 can be formed in the vicinity of the first surface F1 by removing the solvent by drying while applying air to the surface of the coating film. The speed of wind flowing in parallel with the upper surface of the coating film is, for example, 3 to 20 m/sec. When the speed is 3 m/s or more, the drying of the component (A) on the surface of the coating film to which wind is applied is promoted, and an effect that a region R1 having a sufficient thickness is easily formed in the vicinity of the first surface F1 of the film-like adhesive 1 is obtained. On the other hand, when the speed is 20 m/s or less, an effect that the appearance of the coating film surface is easily maintained is obtained.

The drying temperature of the adhesive varnish is, for example, 25 to 150° C., and may be 60 to 145° C. or 70 to 140° C. When the drying temperature is 70° C. or higher, an effect of easily maintaining productivity is obtained, and on the other hand, when the drying temperature is 150° C. or lower, an effect of easily suppressing appearance defects is obtained.

The support film 5 is not particularly limited as long as it can withstand the heating and drying described above, and may be, for example, a polyester film, a polypropylene film, a polyethylene terephthalate film, a polyimide film, a polyetherimide film, a polyether naphthalate film, a polymethylpentene film, or the like. The support film 5 may be a multilayer film obtained by combining two or more kinds, or may have a surface treated with a silicone-based or silica-based release agent or the like. The thickness of the support film 5 may be, for example, 10 to 200 μm or 20 to 170 μm.

Mixing or kneading can be performed by using a disperser such as an ordinary stirrer, a stirrer, a three-roll, or a ball mill, and appropriately combining these. The solvent used for preparing the adhesive varnish is not limited as long as it can uniformly dissolve, knead, or disperse each component, and conventionally known solvents can be used. Examples of such a solvent include ketone-based solvents such as acetone, methyl ethyl ketone, methyl isobutyl ketone, and cyclohexanone, dimethylformamide, dimethylacetamide, N-methyl-2-pyrrolidone, toluene, and xylene. The solvent may be methyl ethyl ketone, cyclohexanone, or the like from the viewpoint of high drying speed and low price. As a method of applying the adhesive varnish to the support film, a known method can be used, and examples thereof include a knife coating method, a roll coating method, a spray coating method, a gravure coating method, a bar coating method, and a curtain coating method.

The surface tension of the adhesive varnish is, for example, 27 to 44 mN/m, and may be 28 to 40 mN/m or 28 to 38 mN/m. When this value is in the above range, an effect that it is easy to produce a film having a good appearance and workability in production is easily maintained is exerted. The surface tension of the adhesive varnish means a value measured by a hanging drop method under conditions of a room temperature of 22 to 28° C. and a humidity of 40 to 60% without wind. The surface tension of the adhesive varnish can be adjusted, for example, by blending a leveling agent into the adhesive varnish.

### Dicing/Die-Bonding Integrated Film

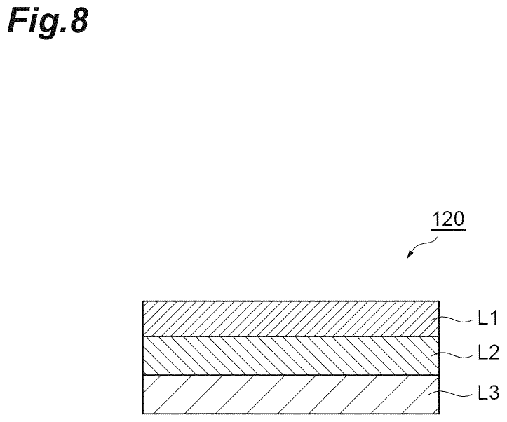

FIG. 8 is a schematic cross-sectional view of a dicing/die-bonding integrated film including the film-like adhesive 1. The dicing/die-bonding integrated film 120 illustrated in this drawing includes a first adhesive layer L1 formed of the film-like adhesive 1, a second adhesive layer L2 in contact with the second surface F2 of the film-like adhesive 1, and a base film L3 in contact with the second adhesive layer L2 in this order. The second adhesive layer L2 and the base film L3 constitute a dicing tape.

### Semiconductor Device

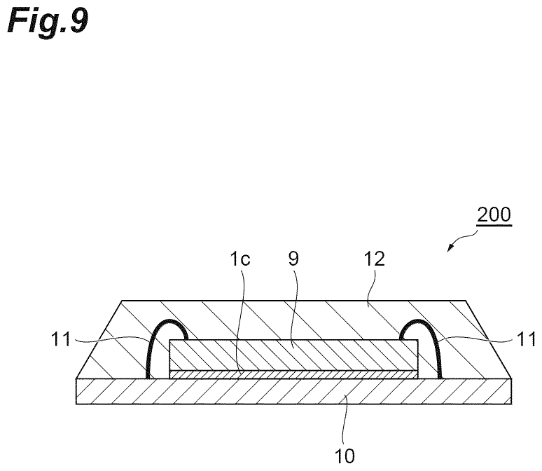

For example, the semiconductor device illustrated in FIG. 9 can be produced using the dicing/die-bonding integrated film 120. A semiconductor device 200 illustrated in FIG. 9 includes a semiconductor chip 9, a support member 10 on which the semiconductor chip 9 is mounted, and a cured product 1c of an adhesive piece provided between the semiconductor chip 9 and the support member 10. The adhesive piece is the diced film-like adhesive 1. The cured product lc bonds the semiconductor chip 9 and the support member 10 together. A connection terminal (not illustrated) of the semiconductor chip 9 is electrically connected to an external connection terminal (not illustrated) via a wire 11, and is sealed by a sealing material 12.

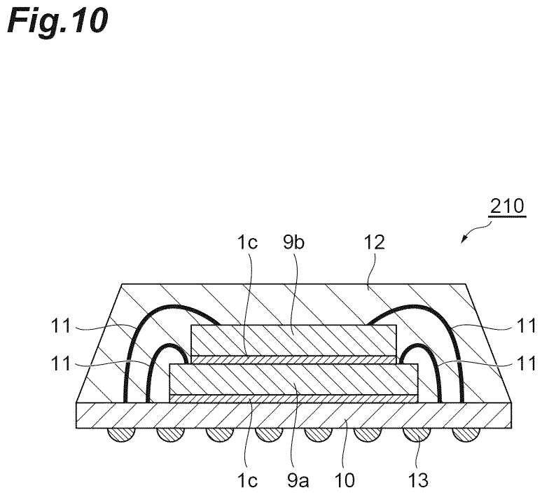

The semiconductor device illustrated in FIG. 10 can also be produced using the dicing/die-bonding integrated film 120. In a semiconductor device 210 illustrated in FIG. 10, a first-stage semiconductor chip 9a is bonded to the support member 10 by the cured product 1c, and a second-stage semiconductor chip 9b is further bonded onto the first-stage semiconductor chip 9a by the cured product 1c. The connection terminals (not illustrated) of the first-stage semiconductor chip 9a and the second-stage semiconductor chip 9b are electrically connected to the external connection terminal via the wire 11, and sealed by the sealing material 12. A terminal 13 is formed on a lower surface of the support member 10.

### Method for Manufacturing Semiconductor Device

The semiconductor devices 200 and 210 are produced through, for example, the following processes.

Attaching a wafer onto the first surface F1 of the first adhesive layer L1 (film-like adhesive) in the dicing/die-bonding integrated film 120.

Singulating the wafer and the first adhesive layer L1 (film-like adhesive) into a plurality of adhesive piece-attached chips.

Picking up the adhesive piece-attached chip from the second adhesive layer L2.

Bonding the chip onto a substrate onto a substrate or another chip via the adhesive piece.

The semiconductor devices 200 and 210 are obtained, for example, by interposing an adhesive piece between the semiconductor chip and the support member or between the semiconductor chip and the semiconductor chip, bonding the semiconductor chip and the support member or the semiconductor chip and the semiconductor chip by thermocompression bonding, and then passing through a wire bonding step, a sealing step with a sealing material, a heating and melting step including reflow by solder, and the like as necessary. The heating temperature in the thermocompression bonding process is usually 20 to 250° C., the load is usually 0.1 to 200 N, and the heating time is usually 0.1 to 300 seconds.

The support member may include a member made of copper. Since the semiconductor devices 200 and 210 are produced using the film-like adhesive 1 having a barrier function of preventing movement of heavy metal ions (for example, copper ions), even in a case where a member made of copper is used as a constituent member of the semiconductor device, an influence of copper ions generated from the member can be reduced, and occurrence of an electrical defect caused by the copper ions can be sufficiently suppressed. Here, examples of the member made of copper include a lead frame, wiring, a wire, a heat dissipation material, and the like, and the influence of copper ions can be reduced even in a cases where the copper is used for any member.

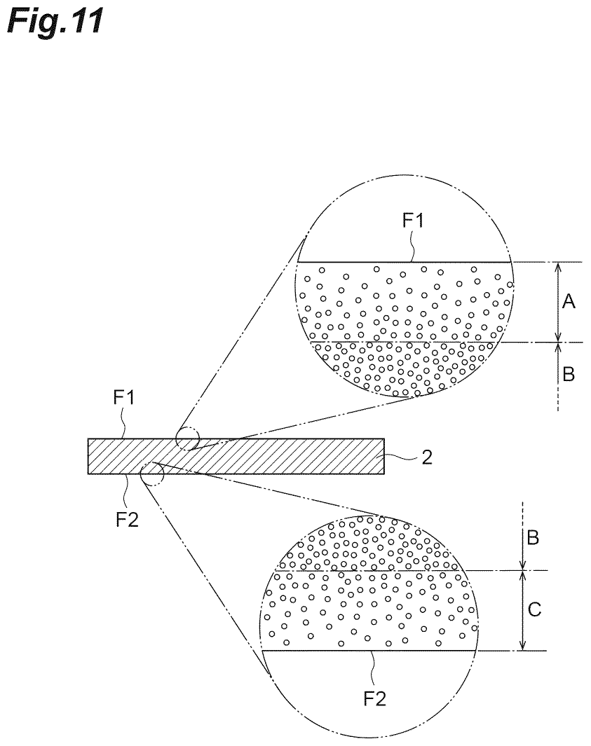

Although the embodiments of the present disclosure have been described in detail above, the present disclosure is not limited to the above embodiments. For example, in the above embodiment, the aspect in which the region A is formed in the vicinity of the first surface F1 has been exemplified, but as illustrated in FIG. 11, a region C similar to the region A may be formed in the vicinity of the second surface F2. A film-like adhesive 2 illustrated in the drawing has the same configuration as the film-like adhesive 1 except that the film-like adhesive 2 further has the region C which is a region in the vicinity of the second surface F2 and in which the content of the filler decreases from the first surface F1 side toward the second surface F2 side. The region C is positioned at a position where the depth from the second surface F2 is shallower than the position of 2 μm. In other words, “the vicinity of the second surface F2” means a region where the depth from the second surface F2 is shallower than the position of 2 μm. It is sufficient that the region C exists in the vicinity of the second surface F2, and for example, a region having a high filler content may locally exist on the second surface F2.

The thickness of the film-like adhesive 2 may be 50 μm or less, and may be, for example, 40 μm or less, 30 μm, 20 μm or less, or 10 μm or less. When the thickness of the film-like adhesive 2 is 50 μm or less, the distance between the semiconductor element and the support member on which the semiconductor element is mounted becomes short, so that defects due to heavy metal ions tend to easily occur, and thus the effect of the present invention is easily obtained. The lower limit of the thickness of the film-like adhesive 2 is not particularly limited, but can be, for example, 2 μm or more. When the thickness of the film-like adhesive 2 is 2 μm or more, a film having a better appearance tends to be easily obtained. The thickness of the region C is, for example, 0.05 to 2 μm, and may be 0.1 to 1.5 μm or 0.3 to 1 μm. When the thickness of the region C is 0.05 μm or more, the region C tends to play a role of preventing the movement of heavy metal ions, and further, when the thickness of the region C is 0.1 μm or more, the region C tends to sufficiently play a role of preventing the movement of heavy metal ions. On the other hand, when the thickness of the region C is 2 μm or less, there is an effect that the handleability of the film-like adhesive 2 is easily maintained. The ratio of the thickness of the region C to the total thickness of the film-like adhesive 2 is, for example, 0.3 to 25%, and may be 1 to 20% or 3 to 15%. When the ratio is 0.3% or more, the region C tends to play a role of hindering the movement of copper ions. Furthermore, when the ratio is 1% or more, the region C tends to sufficiently play a role of hindering the movement of heavy metal ions. On the other hand, when the ratio is 25% or less, an effect that the mechanical strength of the film-like adhesive 2 can be maintained is exhibited.

The present disclosure relates to the following matters.

[1] A film-like adhesive formed of a resin composition having thermosetting properties and containing a filler, the film-like adhesive having a single layer structure including a first surface and a second surface,
in which the film-like adhesive has a region A in a vicinity of the first surface, the region in which a content of the filler decreases from the second surface side toward the first surface side; and
a region B in which the content of the filler does not substantially change from the region A of the film-like adhesive toward the second surface side,
in which when the film-like adhesive is cured by heating, the film-like adhesive satisfies Formula (1) below:

$$a \times ( b / c ) > 50 \qquad ( 1 )$$

in which a thickness of a region A of the film-like adhesive after thermal curing is a (nm), an elastic modulus of a region B is b (Pa), and an elastic modulus at a cleaved surface of mica is c (Pa).

[2] The film-like adhesive according to [1], in which a thickness of the region A is 2 μm or less.

[3] The film-like adhesive according to [1] or [2], in which a ratio of a thickness of the region A to a total thickness of the film-like adhesive is 0.3 to 25%.

[4] The film-like adhesive according to any one of [1] to [3], in which the region A is positioned at a position where a depth from the first surface is shallower than a position of 2 μm.

[5] The film-like adhesive according to any one of [1] to [4], in which a content of the filler is 3 to 55 mass % based on a total mass of the resin composition.

[6] The film-like adhesive according to any one of [1] to [5], in which the resin composition contains an acrylic rubber, and a content of the acrylic rubber is 50 to 85 mass % based on a total mass of the resin composition.

[7] An adhesive film including
the film-like adhesive according to any one of [1] to [6], and
a base film in contact with the second surface of the film-like adhesive.

[8] A dicing/die-bonding integrated film including,
a first adhesive layer formed of the film-like adhesive according to any one of [1] to [6],
a second adhesive layer in contact with the second surface of the film-like adhesive, and
a base film in contact with the second adhesive layer,
in which the dicing/die-bonding integrated film includes the first adhesive layer, the second adhesive layer, and the base film in order.

[9] A method for manufacturing a semiconductor device, the method including
attaching a wafer onto the first surface of the film-like adhesive in the dicing/die-bonding integrated film according to [8],
singulating the wafer and the film-like adhesive into a plurality of adhesive piece-attached chips;
picking up the adhesive piece-attached chip from the second adhesive layer, and
bonding the chip onto a substrate or another chip via the adhesive piece.

### EXAMPLES

Hereinafter, the present disclosure will be specifically described based on examples and comparative examples. Note that the present invention is not limited to the following examples.

### Examples 1 to 4 and Comparative Example 1

### Manufacture of Film-Like Adhesive

### Preparation of Adhesive Varnish

The acrylic rubber solutions illustrated in Tables 1 and 2 were used as adhesive varnishes. The numerical values relating to the compositions shown in Tables 1 and 2 mean parts by mass of the solid content of the acrylic rubber solution.

### Epoxy Resin

N-500P-10 (Trade name, o-cresol novolac epoxy resin manufactured by DIC Corporation, epoxy equivalent: 203 g/eq)

### Curing Agent (Phenol Resin)

MEH-7800M (Trade name: phenol novolac-type phenolic resin, manufactured by MEIWA KAGAKU KOUGYOU CO.,LTD, hydroxyl group equivalent: 175 g/eq, softening point: 61 to 90° C.)
PSM-4326 (Trade name: manufactured by Gun Ei Chemical Industry Co., Ltd., softening point: 120° C.)

### Acrylic Rubber

SG-P3 Modified Product 1 (Trade name: manufactured by Nagase ChemteX Corporation)
The acrylic rubber of SG-P3 Modified Product 2 (Trade name: manufactured by Nagase ChemteX Corporation) excluding a constituent unit derived from acrylonitrile.

### Inorganic Filler

R972 (Trade name, silica particles manufactured by NIPPON AEROSIL CO., LTD., average particle diameter: 0.016 μm)
SC2050-HLG (Trade name, silica filler dispersion liquid manufactured by ADMATECHS COMPANY LIMITED, average particle diameter: 0.50 μm)

### Coupling Agent

Z-6119 (Trade name: 3-ureidopropyltriethoxysilane, manufactured by Dow Toray Co., Ltd.)
A-189 (Trade name: γ-mercaptopropyltrimethoxysilane, manufactured by Nippon Unicar Company Limited)

### Leveling Agent

BYK-333: Polyether-modified polydimethylsiloxane (manufactured by BYK Japan KK)
BYK-325N: Polyether-modified polymethylalkylsiloxane (manufactured by BYK Japan KK)

### Curing Accelerator

2PZ-CN (Trade name: 1-cyanoethyl-2 phenylimidazole, manufactured by SHIKOKU CHEMICALS CORPORATION)

### Manufacture of Film-Like Adhesive

### Examples 1 to 4 and Comparative Example 1

The adhesive varnishes having compositions shown in Tables 1 and 2 were filtered through a 100 mesh filter and vacuum-defoamed. The surface tension (hanging drop method) of the obtained adhesive varnish was 36 mN/m. A 38 μm-thick polyethylene terephthalate (PET) film subjected to a release treatment was prepared as a base film, and the adhesive varnish after vacuum defoaming was applied onto a PET film. The application amount of the adhesive varnish was adjusted so that the thickness after drying was 20 μm. The applied adhesive varnish was dried under the conditions shown in Tables 1 and 2 to obtain a film-like adhesive in the B-stage state. In the table, “wind” and “presence” mean that the adhesive varnish was dried under the condition that the speed of wind flowing in parallel with the upper surface of the coating film was 3 m/s or more, and “wind” and “absence” mean that the adhesive varnish was dried under the condition that the speed of wind flowing in parallel with the upper surface of the coating film was substantially 0 m/s or more.

### Comparative Example 2

A film-like adhesive was prepared in the same manner as in Example 1, and then a surface layer on a surface (first surface) side of the film-like adhesive was removed. That is, a region having a depth of about 0.6 μm from the surface of the film-like adhesive was removed using a plasma processing system PX-250 (manufactured by Nippo Electronics Co., Ltd.) so that the resin-rich region was removed.

### Thickness and Elastic Modulus

The film-like adhesives of Examples 1 to 6 and Comparative Examples 1 and 2 were heated at 170° C. for 3 hours to be cured. Next, the cured film-like adhesive was fixed to a sample stage of an atomic force microscope (SPM400, manufactured by Hitachi High-Tech Corporation), and a cantilever (manufactured by Hitachi High-Tech Corporation, trade name SI-DF-40, material Si, spring constant 40 N/m, tip curvature radius 8 nm) was placed on a cantilever holder to obtain a force curve. The force curve of the region where the cantilever was pushed into the obtained sample was converted into a curve showing the relationship between the elastic modulus and the distance from the first surface (the indentation depth of the cantilever) using the Hertz contact theory. At this time, the cantilever spring constant was corrected, the state of the cantilever was monitored, and it was confirmed that no obvious abrasion and deterioration were observed. The distance from the first surface when the saturation of the obtained curve was reached was read as the thickness of the region A (point A illustrated in FIG. 2), and the elastic modulus when the saturation value was reached (point B illustrated in FIG. 2) was read as the elastic modulus of the region B. The above measurement was performed 10 times, and the average value (a) of the thickness of the region A and the average value (b) of the elastic modulus of the region B were calculated, and are shown in Tables 1 and 2.

In addition, mica (mica standard sample manufactured by Hitachi High-Tech Corporation) was cleaved to have a thickness of 5 μm or more, and indentation measurement was performed on the cleaved surface to obtain a force curve. The force curve of the region where the cantilever was pushed into the obtained mica was converted into a curve showing the relationship between the elastic modulus and the thickness of mica (the indentation depth of the cantilever) using the Hertz contact theory. At this time, the cantilever spring constant was corrected from the resonance frequency by Q curve measurement. The elastic modulus when the saturation of the obtained curve was reached was read as the elastic modulus (c) of mica. Then, the parameter X (nm) was calculated from the following equation.

$$Parameter X = a \times ( b / c )$$

### Evaluation of Copper Ion Permeation Suppressing Effect

### Preparation of Liquid A

Anhydrous copper (II) sulfate (2.0 g) was dissolved in distilled water (1020 g) and stirred until copper sulfate was completely dissolved to prepare a copper sulfate aqueous solution having a copper ion concentration of 500 mg/kg in terms of Cu element. The obtained copper sulfate aqueous solution was used as a liquid A.

### Preparation of Liquid B

1.0 g of anhydrous sodium sulfate was dissolved in 1000 g of distilled water, and the mixture was stirred until the sodium sulfate was completely dissolved. To the resulting solution, 1000 g of N-methyl-2-pyrrolidone (NMP) was further added, and the resulting mixture was stirred. Thereafter, air cooling was performed until the temperature reached room temperature to obtain an aqueous sodium sulfate solution. The obtained solution was designated as a liquid B.

### Measurement of Copper Ion Permeation Time

Each of the film-like adhesive (thickness: 10 μm) of examples and comparative examples prepared above was cured, and then cut into a circle having a diameter of about 3 cm. Next, two silicon packing sheets having a thickness of 1.5 mm, an outer diameter of about 3 cm, and an inner diameter of 1.8 cm were prepared. The film-like adhesive cut into a circular shape was sandwiched between two silicon packing sheets, which were sandwiched between flange portions of two glass cells having a volume of 50 mL, and fixed with a rubber band.

Next, 50 g of the liquid A was injected into one glass cell, and then 50 g of the liquid B was injected into the other glass cell. As a carbon electrode, March Carbon (Manufactured by STAEDTLER Mars GmbH & Co. KG, φ2 mm/130 mm) was inserted into each cell. With the liquid A side as an anode and the liquid B side as a cathode, the anode and a direct current power supply (DC power supply AD-9723D manufactured by A&D Company, Limited) were connected. In addition, the cathode and the DC power supply were connected in series via an ammeter (Degital multimeter PC-720M manufactured by Sanwa Electric Instrument Co., Ltd.). A voltage was applied at an applied voltage of 24.0 V at room temperature, and the measurement of the current value was started after the voltage was applied. The measurement time was up to 500 minutes, and the rise time of the current value was defined as the copper ion permeation time. The rise time was a time when the current value reached 1.0 μA. In this evaluation, it can be said that the slower the rise time of the current value, the more the copper ion permeation is suppressed. Evaluation was performed according to the following criteria. The results are shown in Tables 1 and 2.
A: The copper ion permeation time is 100 minutes or longer.
B: The copper ion permeation time is 60 minutes or longer and shorter than 100 minutes.
C: The copper ion permeation time is shorter than 60 minutes.

TABLE 1

| | | Example 1 | Example 2 |
|---|---|---|---|
| Composition | N-500P-10 | 10.0 | 10.0 |
| (parts by mass) | MEH-7800M | 10.0 | 10.0 |
| | PSM-4326 | — | — |
| | SG-P3 Modified | 70.0 | 70.0 |
| | Product 1 | | |
| | SC2050-HLG | — | — |
| | R972 | 8.0 | 8.0 |
| | z-6119 | 1.0 | 1.0 |
| | A-189 | 0.50 | 0.50 |
| | BYK-333 | — | — |
| | BYK-325N | — | — |
| | 2PZ-CN | 0.02 | 0.02 |

| | | |
|---|---|---|
| Varnish surface tension (mN/m) | 36 | 36 |
| Wind | Present | Present |
| Removal processing of surface | Absent | Absent |
| Drying temperature (° C.) | 105 | 130 |
| Thickness a of region A (nm) | 600 | 540 |
| Parameter X (nm) | 128 | 115 |
| Copper ion permeation suppressing effect | B | B |

TABLE 2

| | | | | Comparative | Comparative |
|---|---|---|---|---|---|
| | | Example 3 | Example 4 | Example 1 | Example 2 |
| Composition | N-500P-10 | 11.0 | 10.0 | 10.0 | 10.0 |
| (parts | MEH-7800M | — | 10.0 | 10.0 | 10.0 |
| by mass) | PSM-4326 | 6.0 | — | — | — |
| | SG-P3 Modified | — | 70.0 | 70.0 | 70.0 |
| | Product 1 | | | | |
| | SG-P3 Modified | 73.0 | — | — | — |
| | Product 2 | | | | |
| | SC2050-HLG | 8.0 | — | — | — |
| | R972 | — | 8.0 | 8.0 | 8.0 |
| | z-6119 | 1.0 | 1.0 | 1.0 | 1.0 |
| | A-189 | 0.50 | 0.50 | 0.50 | 0.50 |
| | BYK-333 | — | — | — | — |
| | BYK-325N | — | — | — | — |
| | 2PZ-CN | 0.02 | 0.02 | 0.02 | 0.02 |

| | | | | |
|---|---|---|---|---|
| Varnish surface tension (mN/m) | 37 | 36 | 36 | 36 |
| Wind | Present | Present | Absent | Present |
| Removal processing of surface | Absent | Absent | Absent | Present |
| Drying temperature (° C.) | 130 | 25 | 25 | 105 |
| Thickness a of region A (nm) | 390 | 250 | 180 | 50 |
| Parameter X (nm) | 133 | 53 | 38 | 11 |
| Copper ion permeation | A | B | C | C |
| suppressing effect | | | | |

### REFERENCE SIGNS LIST

1, 2 Film-like adhesive
1c Cured product
5 Support film
9, 9a, 9b Semiconductor chip
10 Support member
11 Wire
12 Sealing material
13 Terminal
100 Adhesive sheet
120 Dicing/die-bonding integrated film
F1 First surface
F2 Second surface
L1 First adhesive layer (film-like adhesive)
L2 Second adhesive layer
L3 Base film
A, B, C Region

1. A film-like adhesive comprising:
a thermosetting resin component; and
a filler,
wherein the film-like adhesive has a single layer structure comprising a first surface and a second surface, and
wherein the film-like adhesive has a region A in a vicinity of the first surface, the region in which a content of the filler decreases in a direction from the second surface toward the first surface; and
wherein the film-like adhesive has a region B in which the content of the filler does not substantially change in a direction from the region A of the film-like adhesive toward the second surface,
wherein when the film-like adhesive is cured by heating, the film-like adhesive satisfies Formula (1) below:
$$a \times ( b / c ) > 50 \qquad ( 1 )$$
wherein a thickness of a region A of the film-like adhesive after thermal curing is a (nm), an elastic modulus of a region B is b (Pa), and an elastic modulus at a cleaved surface of mica is c (Pa).

2. The film-like adhesive according to claim 1, wherein a thickness of the region A is 2 μm or less.

3. The film-like adhesive according to claim 1, wherein a ratio of a thickness of the region A to a total thickness of the film-like adhesive is 0.3 to 25%.

4. The film-like adhesive according to claim 1, wherein the region A is positioned at a position where a depth from the first surface is shallower than a position of 2 μm.

5. The film-like adhesive according to claim 1, wherein a content of the filler is 3 to 55 mass % based on a total mass of the film-like adhesive.

6. The film-like adhesive according to claim 1, wherein the film-like adhesive comprises an acrylic rubber, and
a content of the acrylic rubber is 50 to 85 mass % based on a total mass of the film-like adhesive.

7. An adhesive film comprising:
the film-like adhesive according to claim 1; and
a base film in contact with the second surface of the film-like adhesive.

8. A dicing/die-bonding integrated film comprising:
a first adhesive layer formed of the film-like adhesive according to claim 1;
a second adhesive layer in contact with the second surface of the film-like adhesive; and
a base film in contact with the second adhesive layer,
wherein the dicing/die-bonding integrated the second adhesive layer located between the first adhesive layer and the base film.

9. A method for manufacturing a semiconductor device, the method comprising:
attaching a wafer onto the first surface of the film-like adhesive in the dicing/die-bonding integrated film according to claim 8;
singulating the wafer and the film-like adhesive to obtain a plurality of adhesive piece-attached chips, each comprising a chip obtained by singulating the wafer, and an adhesive piece obtained by singulating the film-like adhesive in contact with the chip;
picking up the adhesive piece-attached chip from the second adhesive layer; and
bonding the chip onto a substrate or another chip via the adhesive piece.

10. The method according to claim 9, wherein a first adhesive piece-attached chip is picked up from the second adhesive layer, the first adhesive piece-attached chip comprising a first chip and a first adhesive piece in contact with the first chip, and the first chip is bonded onto the substrate via the first adhesive piece, and
wherein a second adhesive piece-attached chip is picked up from the second adhesive layer, the second adhesive piece-attached chip comprising a second chip and a second adhesive piece in contact with the second chip, and the second chip is bonded onto the first chip on the substrate via the second adhesive piece.

11. The film-like adhesive according to claim 1, wherein the film-like adhesive comprises a coupling agent.

12. The film-like adhesive according to claim 1, wherein the film-like adhesive comprises a leveling agent.

13. The film-like adhesive according to claim 1, wherein the film-like adhesive comprises a curing accelerator.

14. The film-like adhesive according to claim 1, wherein a content of the filler is 7 to 40 mass % based on a total mass of the film-like adhesive.

15. The film-like adhesive according to claim 1, wherein an average particle diameter of the filler is 0.01 to 1 μm.

16. The film-like adhesive according to claim 1, wherein an average particle diameter of the filler is 0.03 to 0.5 μm.

17. The film-like adhesive according to claim 1, wherein a thickness of the film-like adhesive is 50 μm or less.

18. The film-like adhesive according to claim 1, wherein a thickness of the region A is 0.3 to 1 μm.
